(19) United States
(12) Patent Application Publication
(10) Pub. No.: US 2017/0005656 A1
(43) Pub. Date: Jan. 5, 2017

(54) High Voltage Input Stage Using Low Voltage Transistors

(71) Applicant: Broadcom Corporation, Irvine, CA (US)

(72) Inventor: John SCHULER, Gilbert, AZ (US)

(73) Assignee: Broadcom Corporation, Irvine, CA (US)

(21) Appl. No.: 14/918,443

(22) Filed: Oct. 20, 2015

Related U.S. Application Data
(60) Provisional application No. 62/188,397, filed on Jul. 2, 2015.

(51) Int. Cl. H03K 17/687; H01L 49/02; H01L 27/02; H01L 27/06; H01L 27/092; H01L 29/78

(52) U.S. Cl. CPC H03K 17/6872; H01L 27/092; H01L 29/7816; H01L 27/0207; H01L 27/0629; H01L 28/20

(57) ABSTRACT

A structure for high voltage input stage for deep submicron is provided that does not include native devices. This structure is able to maintain high speed functionality without jeopardizing device reliability or DC (direct current) power consumption. A circuit apparatus includes a first stage that receives an input signal having an input voltage range and generates a first intermediary output signal and a second intermediary output signal. The first stage includes an N-type field effect transistor (NFET) circuit that receives the input signal and generates the first intermediary output signal, where the first intermediary output signal substantially follows the input signal in a first region of the input voltage range and is substantially constant in a second region of the input voltage range. The first stage further includes a P-type field effect transistor (PFET) circuit that receives the input signal and generates the second intermediary output signal, where the second intermediary output signal is substantially constant in the first region of the input voltage range and substantially follows the input signal in the third region of the input voltage range. The circuit apparatus further includes a second stage that receives the first intermediary output signal and the second intermediary output signal and generates a third intermediary output signal.

### CROSS REFERENCE TO RELATED APPLICATIONS

The present application claims the benefit of U.S. Provisional Patent Application No. 62/188,397, filed on Jul. 2, 2015, which is hereby incorporated by reference in its entirety.

### BACKGROUND

Field

The present disclosure relates generally to a high voltage input stage using low voltage transistors without using any special transistors such as a special LDMOS (laterally diffused metal oxide semiconductor) transistor or a native transistor (a transistor with threshold voltage of zero).

Background Art

Designing high voltage interface input/outputs (IOs) using thin oxide devices has been a challenge in deep submicron technologies. For example, high voltage input stages designed based on a 28 nanometer (28 nm) or 20 nm semiconductor device fabrication technology typically include one or more native devices (e.g., transistors with threshold voltage of zero such as native field-effect transistor (FET)). The native devices enable the input stage to turn on fully over a range of signal amplitudes. However, native devices are not available for some deep submicron processes, such as 16 nm technology.

### BRIEF DESCRIPTION OF THE DRAWINGS/FIGURES

The accompanying drawings, which are incorporated herein and form part of the specification, illustrate the present disclosure and, together with the description, further serve to explain the principles of the disclosure and to enable a person skilled in the relevant art(s) to make and use the disclosure.

FIG. 1 illustrates a conventional input stage circuit.

FIG. 2a illustrates an input stage circuit, in accordance with an embodiment of the present disclosure,

FIG. 2b illustrates an LDMOS replacement circuit, in accordance with an embodiment of the present disclosure.

FIG. 3a illustrates an input stage circuit, in accordance with another embodiment of the present disclosure.

FIG. 3b illustrates a differential input stage circuit, in accordance with another embodiment of the present disclosure.

FIG. 4 illustrates intermediary output signals and the output signal, in accordance with an embodiment of the present disclosure.

The present disclosure will now be described with reference to the accompanying drawings. In the drawings, generally, like reference numbers indicate identical or functionally similar elements. Additionally, generally, the left-most digit(s) of a reference number identifies the drawing in which the reference number first appears.

### DETAILED DESCRIPTION

### Overview

A structure for a high voltage input stage for deep submicron is provided that does not include native devices. This structure is able to maintain high speed functionality without jeopardizing device reliability or DC (direct current) power consumption.

According to one embodiment of the disclosure, a circuit apparatus includes a first stage that receives an input signal having an input voltage range and generates a first intermediary output signal and a second intermediary output signal. The first stage includes an N-type field effect transistor (NFET) circuit that receives the input signal and generates the first intermediary output signal, where the first intermediary output signal substantially follows the input signal in a first region of the input voltage range and is substantially constant in a second region of the input voltage range. The first stage includes a P-type field effect transistor (PFET) circuit that receives the input signal and generates the second intermediary output signal, where the second intermediary output signal is substantially constant in the first region of the input voltage range and substantially follows the input signal in the second region of the input voltage range. The circuit apparatus further includes a second stage that receives the first intermediary output signal and the second intermediary output signal and generates a third intermediary output signal.

According to another embodiment of the disclosure, a circuit apparatus includes a P-type field effect transistor (PFET) circuit of a first stage that includes a first PFET including a gate coupled to a first power supply, a drain coupled to an input port, and a source, and a second PFET including a gate coupled to the input port, a drain coupled to the first power supply, and a source coupled to the source of the first PFET. The circuit further includes an N-type field effect transistor (NFET) circuit of the first stage that includes a first NFET including a gate coupled to a second power supply, a drain coupled to the input port, and a source, and a second NFET including a gate coupled to the input port, a drain coupled to the second power supply, and a source coupled to the source of the first NFET.

### DETAILED DISCUSSION

The following Detailed Description of the present disclosure refers to the accompanying drawings that illustrate exemplary embodiments consistent with this disclosure. The exemplary embodiments will so fully reveal the general nature of the disclosure that others can, by applying knowledge of those skilled in relevant art(s), readily modify and/or adapt for various applications such exemplary embodiments, without undue experimentation, without departing from the spirit and scope of the disclosure. Therefore, such adaptations and modifications are intended to be within the meaning and plurality of equivalents of the exemplary embodiments based upon the teaching and guidance presented herein. It is to be understood that the phraseology or terminology herein is for the purpose of description and not of limitation, such that the terminology or phraseology of the present specification is to be interpreted by those skilled in relevant art(s) in light of the teachings herein. Therefore, the detailed description is not meant to limit the present disclosure.

The embodiment(s) described, and references in the specification to “one embodiment”, “an embodiment”, “an example embodiment”, etc., indicate that the embodiment(s) described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to effect such feature, structure, or characteristic in connection with other embodiments whether or not explicitly described.

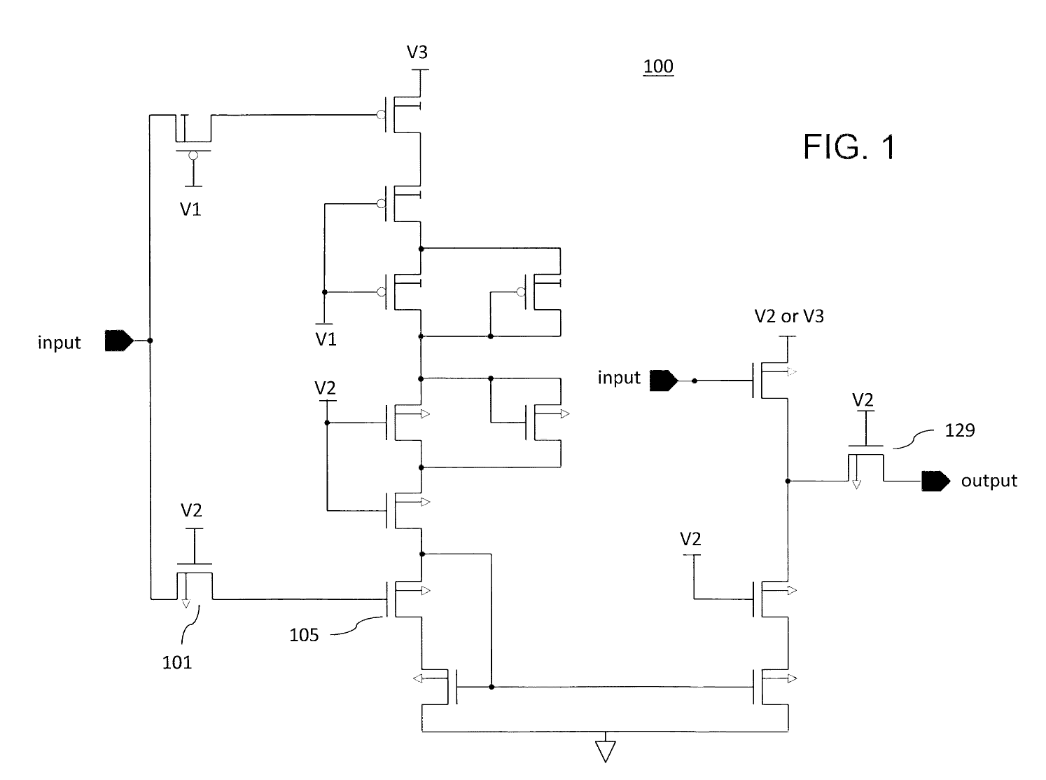

FIG. 1 illustrates a conventional input stage circuit 100. Input stage circuit 100 can be designed for and fabricated with a 28 nanometer (28 nm) or 20 nm semiconductor device fabrication technology. Input stage circuit 100 includes two native devices—transistor 101 and transistor 129. According to this example, native devices 101 and 129 have threshold voltages of zero, and therefore, can be turned-on (i.e. conducting) without any gate voltage applied. In fact, native devices 101 and 129 are turned-on until a negative gate voltage (e.g., relative to the source voltage) is applied, assuming the transistors are field effect transistors (FETs) as shown. Transistor 101 ensures that transistor 105 can turn on fully. Also, transistor 129 can ensure that the subsequent stages receive a sufficiently high voltage to operate.

According to this example, native transistor 101 can be an n-type FET with its gate connected to power supply V2. In this example, when the amplitude of the input signal is less than V2, transistor 101 is on and its source that is connected to transistor 105 follows the voltage of the drain of transistor 101, which is the input signal voltage. The input signal can be between approximately 0 to 3.3 volts (or in some cases 3.6 volts.) When the input signal becomes greater than V2, transistor 101 shuts off and its source will maintain its voltage depending on the residual capacitance at the source of transistor 101. In other words, the source of the transistor 101 can follow the input signal until the input signal reaches V2. At that point, the source of the transistor 101 maintains its voltage. This occurs because transistor 101 is a native device with a threshold voltage of zero.

If input stage circuit 100 is to be fabricated using a deep submicron process, such as 16 nm technology, that do not support native devices, then transistor 101 will have a threshold of approximately 0.7 volts. Assuming V2 to be approximately 1.6 volts (in some examples V2 can have a voltage of 1.8 volts), transistor 101 will shut off when the input signal goes above 0.9 volts (1.6−0.7). If transistor 101 has a threshold of approximately 0.9 volts, transistor 101 will shut off when the input signal goes above 0.7 volts (1.6−0.9). In that case, the voltage at the gate of transistor 105 would be less than or close to the voltage threshold of transistor 105. Therefore, there is a high probability that transistor 105 never turns on and input stage 100 will not operate.

In this example, transistor 129 is also a native device (e.g., a native n-type FET), such that it can switch between 0 and V2. If transistor 129 is not a native device, it will provide at most V2-0.7 volts to the next stage of the circuit (not shown). This output voltage might be less than what the next stage needs for operation. Therefore, the next stage might be either inoperable or operate poorly.

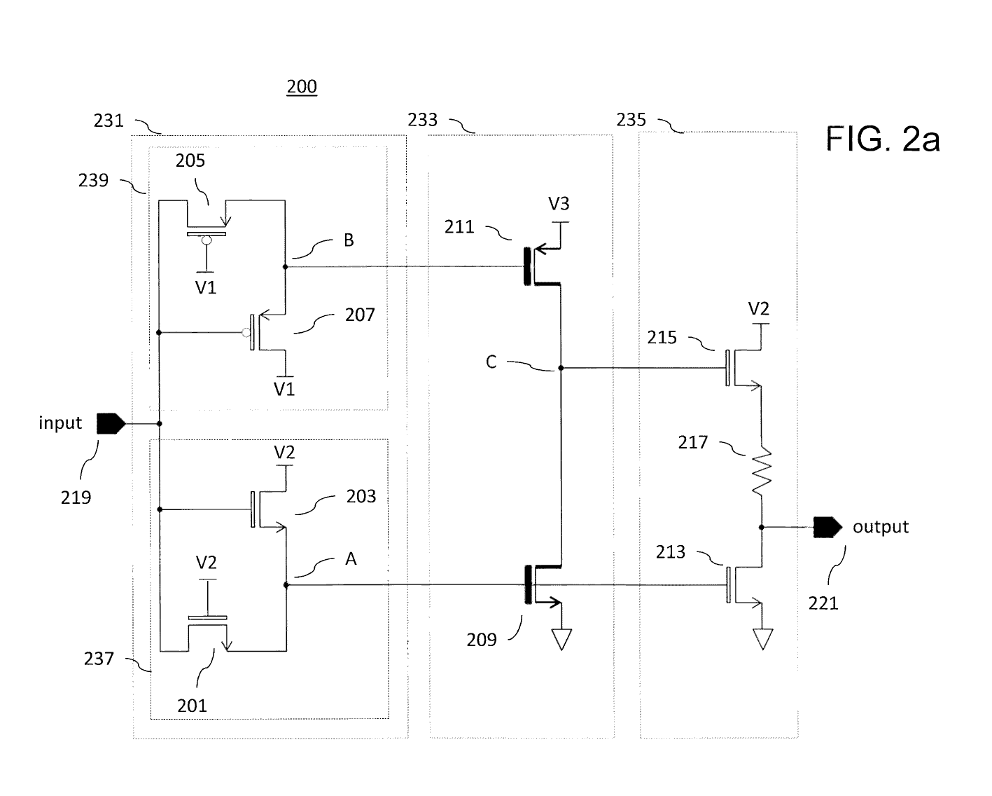

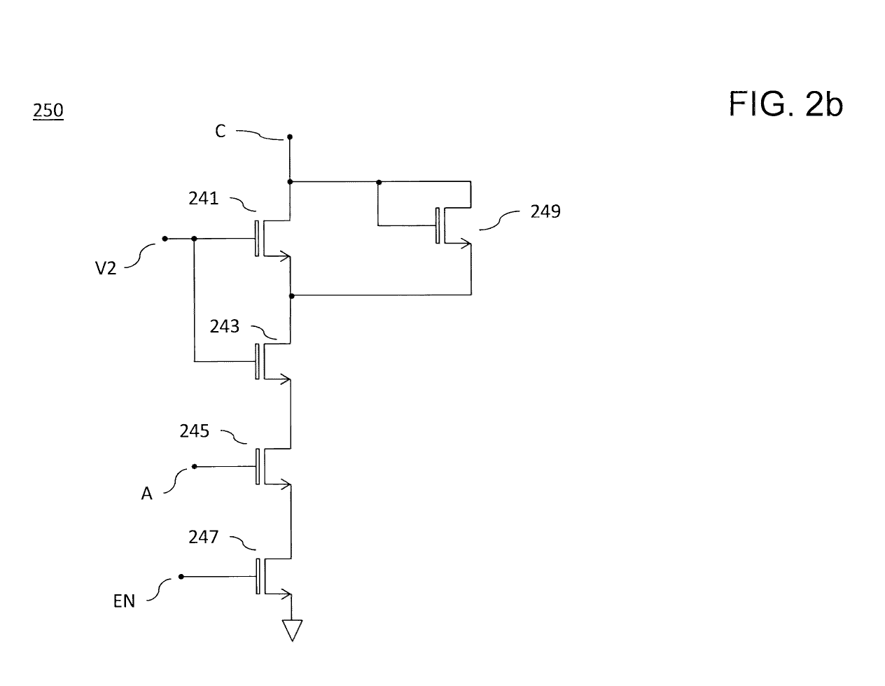

The embodiments of this disclosure discussed with respect to FIGS. 2-4 disclose high voltage input stages configured to perform similar functionality of circuit 100 but without using any native devices.

FIG. 2a illustrates an input stage circuit, in accordance with an embodiment of the present disclosure. Input stage circuit 200 can include three main stages. A first stage 231, a second stage 233, and a third stage 235.

In one example, first stage 231 includes an n-type FET circuit 237 including two n-type FETs 201 and 203 and a p-type FET circuit 239 including two p-type FETs 205 and 207. In this example, the drain of transistor 201 is connected to input port 219. AL input signal to input port 219 can be approximately between 0-3.3 volts, or up to 3.6 volts in examples. The gate of transistor 201 can be connected to voltage source V2 that can have a voltage of approximately 1.6 volts, or up to 1.8 volts in examples. The source of transistor 201 is connected to the source of transistor 203. The drain of transistor 203 is connected to voltage source V2. The gate of transistor 203 is connected to the input port 219.

NFETs (such as NFETs 201, 203) and PFETs (such as 205 and 207) are distinct from native FETs as will be understood by those skilled in arts. Namely, NFETs are doped n-type so as to produce a channel with excess electrons under proper bias conditions and PFETs are doped p-type so as to produce a channel with excess holes under proper bias conditions. Further, both NFETs and PFETs have an inherent threshold voltage that must be overcome to form their respective channels for current to conduct and the transistors to be “on.” Whereas, native devices are undoped relative to NFETs and PFETs, and do not have a threshold voltage. Accordingly, native FETs are nominally “on”, unless a bias voltage is applied to turn them “off.” For example, a negative gate voltage relative to the source voltage can be applied to turn native FETs off

When the amplitude of the input signal received at input port 219 is approximately between 0 and V2-vt, where vt is the threshold voltage of transistor 201, transistor 201 is on. Therefore, the voltage at node A (at the source of transistor 201) follows the input voltage. In other words, node A is connected directly to input port 219. During this time transistor 203 is off.

When the amplitude of the input signal increases between V2-vt to V2, transistor 201 transitions to off and transistor 203 transitions to on. Therefore, in the transition period, as transistor 201 is turning off, transistor 203 is turning on. In one example, vt is approximately 0.7 volts. Threshold voltage vt can have other values, such as approximately 0.9 volts.

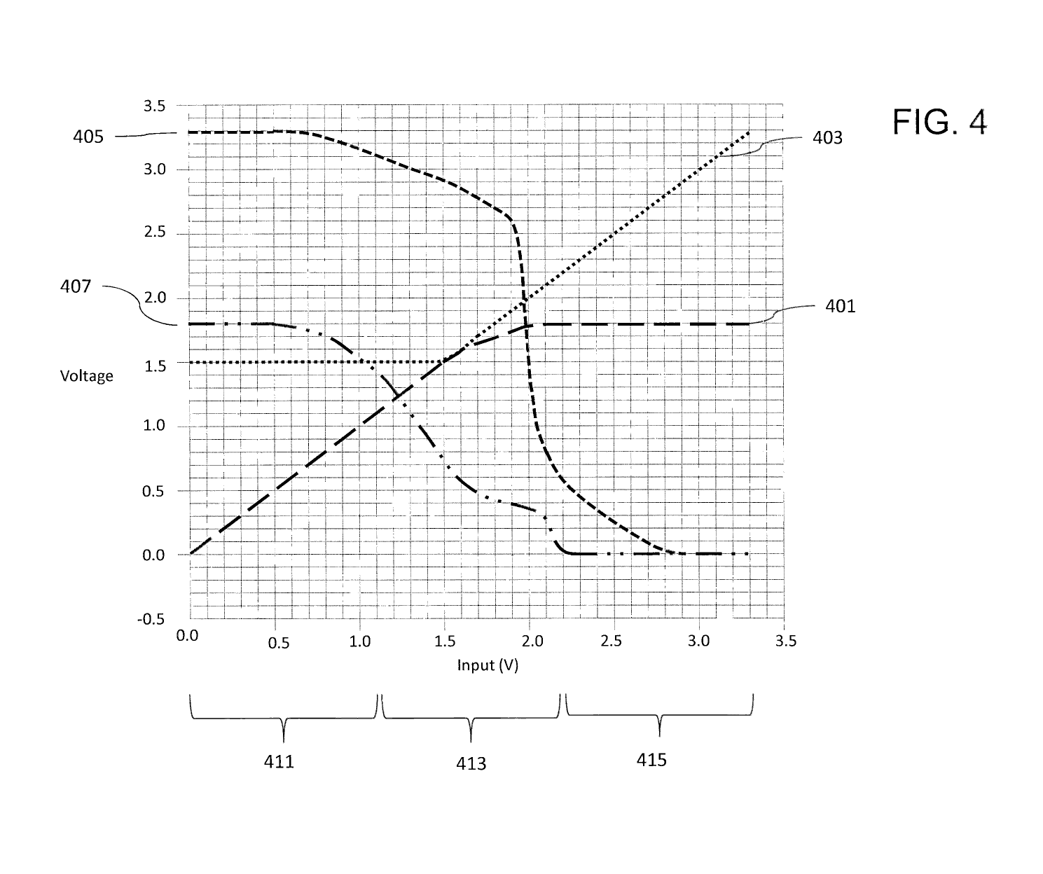

When the amplitude of the input signal increases to more than V2, transistor 201 is off and transistor 203 is on. Therefore, the voltage at node A (e.g., an intermediary output signal) will be equal to V2. When the input signal increases over V2, the voltage at node A will be fixed at V2. This behavior is illustrated, by example, in FIG. 4. Plot 401 illustrates the voltage at node A when the amplitude of the input voltage increases from 0 to approximately 3.3 volts. In region 411, between 0 and V2-vt (in one example, approximately 1.8−0.7 volts=1.1 volts), transistor 201 is on and transistor 203 is off In this region 411, the voltage at node A follows the input signal. In a transition region including or within a region 413, when the amplitude of the input signal is between V2-vt and V2 (e.g., between approximately 1.1 and approximately 1.8 volts), transistor 201 is turning off and transistor 203 is turning on. Voltage at node A approximately follows the input signal at this transition region in region 413, but less accurately as it tends toward saturation. In region 415 (and/or a region slightly larger than and including region 415), when the amplitude of the input signal is above V2, the voltage at node A is constant at V2 and no longer follows the input voltage for increasing amplitudes.

As indicated, first stage 231 further includes p-type FET circuit 239, which includes two p-type FETs 205 and 207. In this example, the drain of transistor 205 is connected to input port 219. The gate of transistor 205 can be connected to voltage source V1 that can have a voltage of approximately 1.5 volts. The source of transistor 205 is connected to the source of transistor 207. The drain of transistor 207 is connected to voltage source V1. The gate of transistor 207 is connected to the input port 219.

When the amplitude of the input signal received at input 219 is approximately between 3.3 volts and V1+vt (in one example, approximately 1.5+0.7 volts=2.2 volts), transistor 205 is on. In this range of input signal, transistor 207 is off. Therefore, the voltage at node B (at the source of transistor 205, e.g., an intermediary output signal) follows the input voltage. In other words, node B is connected directly to input port 219.

When the amplitude of the input signal decreases between V1+vt to V1, transistor 205 transitions to off and transistor 207 transitions to on. Therefore, in the transition period, as transistor 205 is turning off, transistor 207 is turning on. In one example, vt is approximately 0.7 volts. Threshold voltage vt can have other values, such as approximately 0.9 volts.

When the amplitude of the input signal decreases from V1 to 0, transistor 205 is off and transistor 207 is on. Therefore, the voltage at node B will be equal to and fixed at V1. This behavior is illustrated, by example, in FIG. 4. Plot 403 illustrates the voltage at node B when the amplitude of the input voltage increases from 0 to approximately 3.3 volts. Between 0 and V1 (in one example, approximately 1.5 volts) transistor 205 is off and transistor 207 is on. In this input voltage range, the voltage at node B is fixed at V1 1.5 volts. This input voltage range includes the region 411 and part of the transition range 413. In a transition region including or within region 413, when the amplitude of the input signal is between V1 and V1+vt (e.g., between approximately 1.5 and approximately 2.2 volts), transistor 207 is turning off and transistor 205 is turning on. Voltage at node B begins to approximately follow the input signal in this transition region within region 413. When the amplitude of the input signal is between V1+vt and 3.3 volts, transistor 205 is on and transistor 207 is off. In this input voltage range, voltage at node B more accurately follows the input signal, which is shown in region 415.

In other words, when the amplitude of the input signal is low (e.g., in region 411), voltage at node A substantially follows the input signal and voltage at node B is substantially fixed at V1. When the amplitude of the input signal is increasing, in a transition period (e.g., region 413), the voltage at node B starts substantially following the input signal while the voltage at node A begins to saturate so as to follow the input signal in a less accurate manner. When the amplitude of the input signal increases past the transition period to region 415, the voltage at node B substantially follows the input signal and voltage at node A is substantially fixed at V2. For high values of the amplitude of the input signal, the voltage at node B follows the input signal and voltage at node A is fixed at V2. One of the requirements of input stage circuit 200 is that when input signal is at its lowest value (approximately 0 volts) or is at its highest value (approximately 3.3 volts), substantially no current will flow in the circuit, By fixing the voltage at nodes B and A when input signal is low or high, respectively, this requirement is met.

According to one example, voltages V2 and V3 are controlled by an external regulator (within, for example, 10% tolerance) such that they will not over-power the circuit. In this example, V1 is controlled by an internal regulator such that V1=V3−V2. In one example, V3 is approximately 3.3 volts and V2 is approximately 1.8 volts, so that V1 is approximately 1.5 volts.

Input stage 200 can include a second stage (an intermediate stage) that can include transistors 209 and 211. In one example, the gate of transistor 209 is connected to node A, the source of transistor 209 is connected to ground, and the drain of transistor 209 is connected to drain of transistor 211. The gate of transistor 211 is connected to node B and the source of transistor 211 is connected to power supply V3. In one example, transistor 209 is an n-type Laterally Defused Metal Oxide Semiconductor (LDMOS) transistor, which has a higher drain-to-gate breakdown voltage and drain-to-source breakdown voltage than non-LDMOS transistors. According to this example, transistor 211 can also be an LDMOS transistor. In this example, the gate-source breakdown of the LDMOS transistors can approximately be 1.8 or 2 volts. But the drain-source break down can go to approximately 3.3 or 3.6 volts. It is noted that although transistors 209 and 211 are shown as LDMOS transistors (represented by the thicker gate regions), however the embodiments of this disclosure are not limited to LDMOS transistors and can include other transistors and/or circuits. For example, FIG. 2b illustrates a circuit that can replace LDMOS transistors. The replacement circuit can include a triple stack cascade structure as illustrated in FIG. 2b. However, other structures can replace the LDMOS transistors that provide similar functionalities.

When the amplitude of the input voltage is high (approximately 3.3 volts), as discussed above, the voltage at node B (e.g., an intermediary output signal) is also high (tracking the input signal), and therefore transistor 211 is off Whereas, the voltage at node A (e.g., an intermediary output signal) is fixed at V2 (≈1.8 volts), so that transistor 209 is on. In this case, the voltage at node C (gate of transistor 215, e.g., an intermediary output signal) is being controlled by NFET section 237 (transistors 201 and 203) of the first stage 231 because the transistor 209 is on. Therefore, the voltage at node C is low (approximately 0 volts) since the drain of transistor 209 will follow the source voltage, which is fixed at ground.

In contrast, when the amplitude of the input voltage is low (approximately 0 volts), as discussed above, the voltage at node A (e.g., an intermediary output signal) is also low (tracking the input signal) and therefore transistor 209 is off Whereas, the voltage at node B (e.g., an intermediary output signal) is fixed at V1 (≈1.5 volts), so that transistor 211 is on, since V3 is approximately 3.3 volts. In this case, the voltage at node C is being controlled by PFET section 239 (transistors 205 and 207) of the first stage 231 because the transistor 211 is on. Therefore, transistor 211 is on (while transistor 209 is off) and the voltage at node C is high (approximately 3.3 volts) since the drain of transistor 211 will follow the source voltage, which is fixed at V3 (≈3.3 volts).

Graph 405 of FIG. 4 further illustrates how the voltage at node C (e.g., an intermediary output signal) changes when the input signal changes between low and high.

Input stage circuit 200 further includes a third stage 235 (e.g., an output stage) that connects the input stage circuit 200 to other circuits. Third stage 225 can include a transistor 213, a resistor 217, and a transistor 215. In this example, the source of transistor 213 is connected to ground. The gate of transistor 213 is connected to node A and the drain of transistor 213 is connected to resistor 217. Also, the drain of transistor 215 is connected to power supply V2. The gate of transistor 215 is connected to node C and the source of transistor 215 is connected to resistor 217. An output signal is taken from output port 221 that is connected the drain of transistor 213. Graph 407 of FIG. 4 further illustrates how the output signal changes when the input signal changes between low and high. As illustrated in FIG. 4, the output voltage of graph 407 has similar shape to graph 405, which is the voltage of node C. The output voltage is capped at V2 and is an inverse of the input voltage, meaning that the output voltage is high when the input voltage is low and the output voltage is low when the input voltage is high. The output voltage is substantially constant at approximately constant at V2 when the input signal is at a substantially low voltage and the output voltage is substantially constant at approximately 0 volts when the input signal is at a substantially high voltage.

Resistor 217 can be used for fine tuning, and especially for the circuit at the next stage that is connected to input stage circuit 200. In one example, the next stage's circuit can be an inverter, a Schmitt trigger, etc. The next stage's circuit can have a threshold voltage that can be fine-tuned using resistor 217. Some tuning can occur by controlling the size of the transistors, such as transistors 213 and/or 215.

As discussed above, first stage 231 uses an n-type FET circuit 237 (transistors 201 and 203) and a p-type FET circuit 239 (transistors 205 and 207) such that the voltages at nodes A and B can follow the input signal but are clamped at V2 and V1, respectively. Therefore, sufficient voltage is provided to operate all the stages and the voltages do not exceed the safe voltages for the transistors. In other words, the output of the n-type FET circuit 237 (transistors 201 and 203) at Node A follows the input signal voltage when the amplitude of the input signal increases from 0 volts. At some point in the input signal range, the first section 237 clamps Node A at V2. Before the n-type FET circuit 237 clamps Node A at V2, the output of the second section 239 (transistors 205 and 207) at Node B starts following the input signal until input signal reaches the high point of its range. When the input signal is low, the output of the p-type FET circuit 239 at Node B is clamped at V1. This design can protect the circuit and the following stages. Further, the n-type and p-type FET circuits of first stage 231 can be viewed as performing similar functions to that of a native transistor, (such as the native transistor 101 of FIG. 1), without actually being native devices. Therefore, this high voltage input stage 200 is configured to perform similar functionality of circuit 100 of FIG. 1, but without using any native devices. As discussed, above native devices are not available for some the advanced semiconductor fabrication technologies (e.g. 20 and 28 nm). Additionally or alternatively, when the voltages at nodes A or B are substantially fixed at V2 or V1, respectively, these voltages are solid voltage without these points being floated around.

FIG. 2b illustrates an LDMOS replacement circuit 250. In one embodiment, the circuit of FIG. 2b can replace transistor 209 of FIG. 2a. A similar circuit can be used to replace transistor 211. In one example, the replacement circuit of FIG. 2a can be smaller than the LDMOS transistors 209 and/or 211. According to this example, the replacement circuit of FIG. 2b can include transistors 241, 243, 245, 247, and 249 that can be non-LDMOS. The non-LDMOS transistors of replacement circuit 250 are arranged in a cascode fashion so as to spread the voltage drop across multiple drain-source junctions of the respective transistors 241-247. As such, the drain of transistor 241 is connected to node C of input stage 200 of FIG. 2a. The drain of transistor 241 is also connected to the drain and the gate of transistor 249. The source of transistor 241 is connected to the source of transistor 249 and the drain of transistor 243. In one example, transistor 249 can be a diode that can protect the replacement circuit of FIG. 2b when it turns on fast. The gates of transistors 241 and 243 are connected to each other and are also connected to power supply V2. The source of transistor 243 is connected to the drain of transistor 245. The gate of transistor 245 is connected to node A of input stage 200 of FIG. 2a. The source of transistor 245 is connected to drain of transistor 247. The source of transistor 247 is connected to ground and the gate of transistor 247 is connected to an enable signal (EN). Alternatively, transistor 247 can be eliminated and the source of transistor 245 can connected to ground.

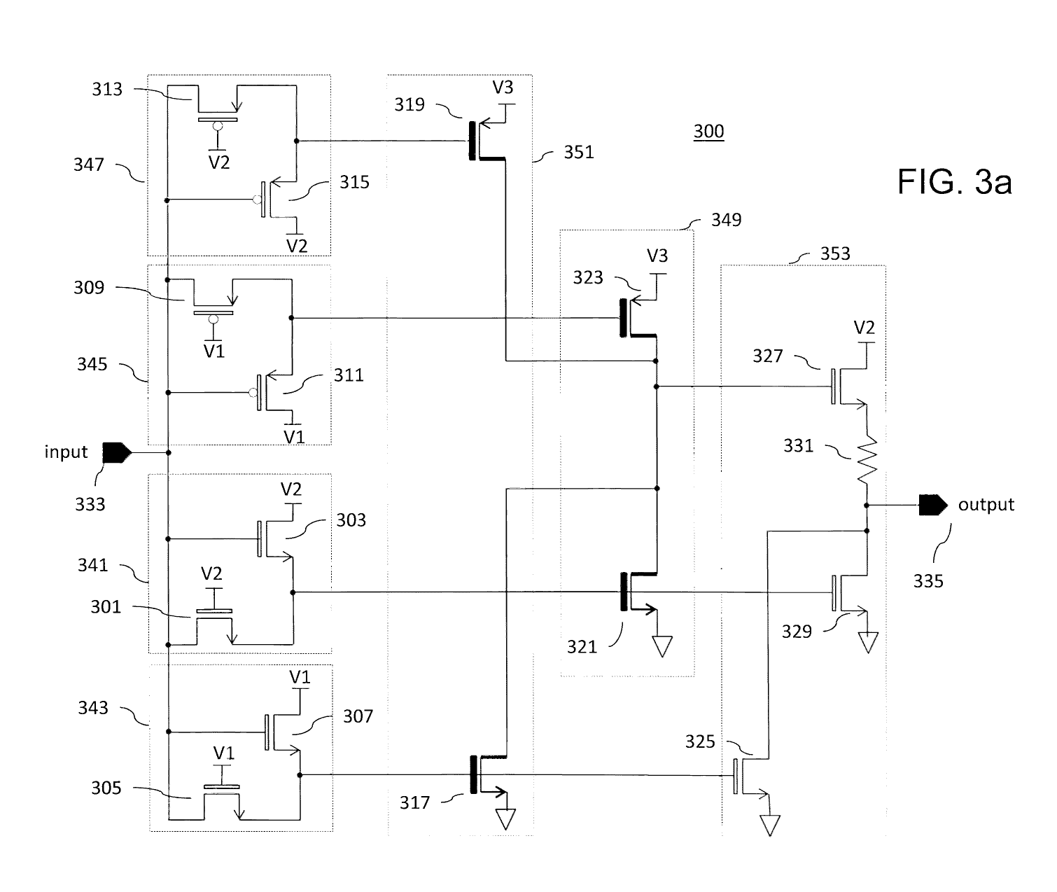

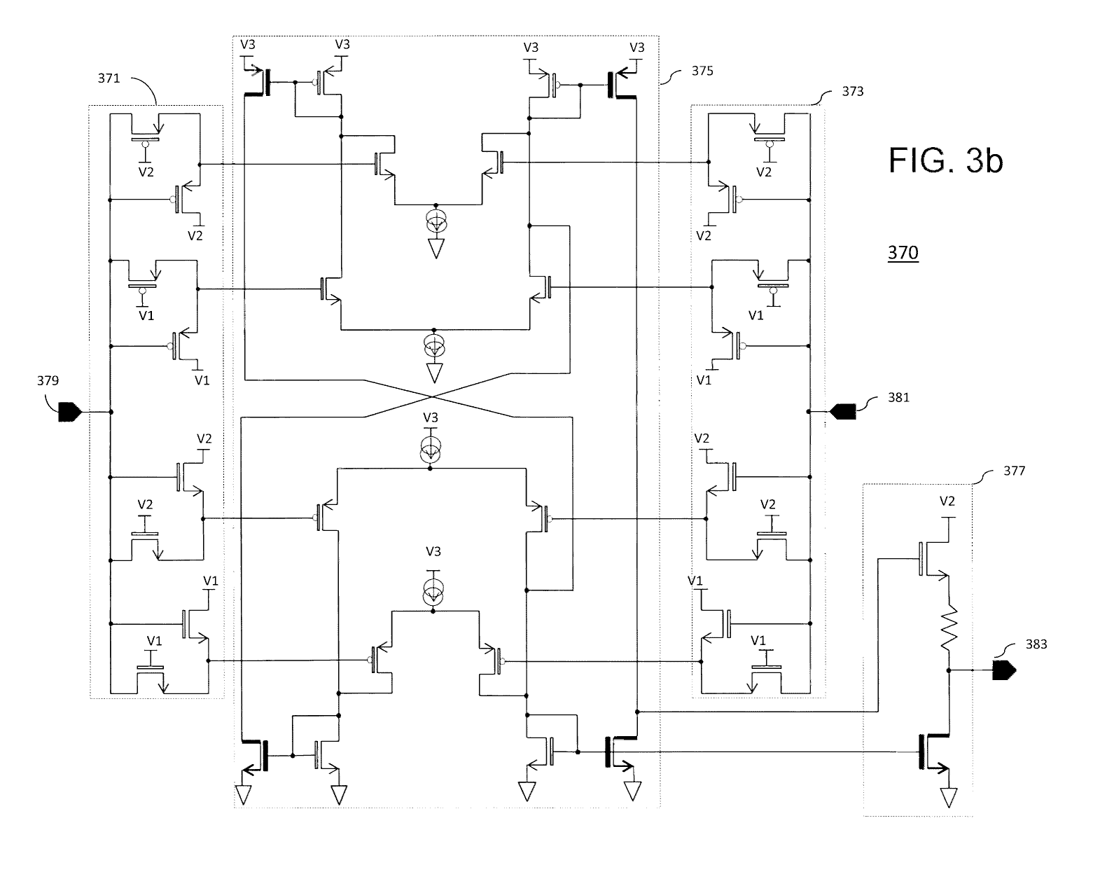

FIG. 3a illustrates an input stage circuit, in accordance with another embodiment of the present disclosure. In this embodiment, additional first and second sections 237 and 239 of first stage 231 and additional second stage 233 is added to input stage 200 of FIG. 2a, where the power supplies of the first and second sections of first stage 231 include both V1 and V2.

In the embodiment of FIG. 2a, if V2 has a lower value (e.g., 10% lower than 1.8 volts) and V3 has a higher value (e.g., 10% higher than 3.3 volts), then input stage circuit 200 can demonstrate a dead zone where the input signal changes but the output signal remains unchanged. For example, plot 401 for the voltage of node A can go to 1.6 volts (instead of 1.8 volts) at the high amplitude of the input voltages. Similarly, if V3 is at 3.6 volts, V1 (which is equal to V3−V2) would be at 2 volts. Therefore, plot 403 for the voltage of node B would go to 2 volts. Therefore, there could be a region where both transistors 209 and 211 are fully on and their gate node will not change in voltage, as they both would be in the flat part of plots 401 and 403. Thus, it would create a dead zone where the input signal changes but there would be no change in the output signal. If this circuit is used as an input stage for an amplifier, for example, the amplifier would not be able to sense the input signal, when the input signal is in the dead zone.

Input stage circuit 300 of FIG. 3 solves the dead zone discussed above. In this example, the n-type FET circuit 237 of the first stage 231 of input stage circuit 200 of FIG. 2a is duplicated in circuit 300 as circuits 341 and 343 in parallel with each other. The circuit 341 includes transistors 301 and 303 and the power supply V2. The circuit 343 includes transistors 305 and 307 and power supply V1.

Similarly, the p-type FET circuit 239 of the first stage 231 of input stage circuit 200 of FIG. 2a is duplicated in circuit 300 as circuits 345 and 347 in parallel with each other. The circuit 345 includes transistors 309 and 311 and the power supply V1. The circuit 347 includes transistors 313 and 315 and power supply V2.

Therefore, even if there is any inaccuracy in voltage supplies V2 and/or V3, at least one of these sections is conducting and therefore, no dead zone will be created.

Input stage circuit 300 also includes a duplicate of second stage 233 of FIG. 2a. For example, input stage circuit 300 can include two second stages 349 and 351. In this example, second stage 349 is coupled to sections 341 and 345. Also, second stage 351 is coupled to sections 343 and 347. Second stages 349 and 351 combine the outputs of first stage 341, 343, 345, and 347.

Further, input stage circuit 300 includes a third stage 353 similar to third stage 235 of FIG. 2a. In this example, third stage 353 further includes transistor 325 that is coupled to section 343.

Input stage circuits 200 and 300 can also be used in a differential form. In this example the input to the circuit is a differential input. Two input stage circuits 300 (or input stage circuits 200) are coupled to each other in a differential form and each part of the differential input signal is fed to each input stage circuit. In one example, this differential input stage can be used in a differential amplifier. Also, this differential amplifier can be used for analog signals. FIG. 3b illustrates a differential amplifier circuit 370, in accordance with another embodiment of the present disclosure.

In this exemplary embodiment, differential amplifier circuit 370 includes two input ports 379 and 381 connected to first stages 371 and 373, respectively. First stage 371 includes NFET sections and PFET sections similar to sections 341, 343, 345, and 347 of input stage 300 of FIG. 3a. First stage 373 is similar to first stage 371.

Circuit 370 also includes a differential amplifier stage 375 that is coupled to first stages 371 and 373. Circuit 370 also includes a third (output) stage 377 that is coupled to the differential amplifier stage 375. Third stage 377 is similar to third stage 235 (e.g., an output stage) of circuit 200 of FIG. 2a. This high voltage differential amplifier circuit 370 is configured to perform similar functionality of circuit 300 of FIG. 300 in a differential manner, and perform differential amplification. Therefore, this high voltage differential amplifier circuit 370 is configured to perform similar functionality of circuit 100 of FIG. 1, in a differential manner, but without using any native devices.

The exemplary embodiments described herein are provided for illustrative purposes, and are not limiting. Other exemplary embodiments are possible, and modifications may be made to the exemplary embodiments within the spirit and scope of the disclosure.

It is to be appreciated that the Detailed Description section, and not the Abstract section, is intended to be used to interpret the claims. The Abstract section may set forth one or more, but not all exemplary embodiments, of the disclosure, and thus, are not intended to limit the disclosure and the appended claims in any way.

The disclosure has been described above with the aid of functional building blocks illustrating the implementation of specified functions and relationships thereof. The boundaries of these functional building blocks have been arbitrarily defined herein for the convenience of the description. Alternate boundaries may be defined so long as the specified functions and relationships thereof are appropriately performed.

It will be apparent to those skilled in the relevant art(s) that various changes in form and detail can be made therein without departing from the spirit and scope of the disclosure. Thus the disclosure should not be limited by any of the above-described exemplary embodiments. Further, the claims should be defined only in accordance with their recitations and their equivalents.

What is claimed is:

1. A circuit apparatus, comprising:
a first stage configured to receive an input signal having an input voltage range and generate a first intermediary output signal and a second intermediary output signal, the first stage comprising:
an N-type field effect transistor (NFET) circuit configured to receive the input signal and generate the first intermediary output signal, wherein the first intermediary output signal substantially follows the input signal in a first region of the input voltage range and is substantially constant in a second region of the input voltage range; and
a P-type field effect transistor (PFET) circuit configured to receive the input signal and generate the second intermediary output signal, wherein the second intermediary output signal is substantially constant in the first region of the input voltage range and substantially follows the input signal in the second region of the input voltage range; and
a second stage configured to receive the first intermediary output signal and the second intermediary output signal and generate a third intermediary output signal.

2. The circuit apparatus of claim 1, further comprising:
a third stage configured to receive the third intermediary output signal and generate an output signal, the output signal being substantially constant when the input signal is at a substantially low voltage or a substantially high voltage.

3. The circuit apparatus of claim 2, wherein the third stage further receives the first intermediary output signal and generates the output signal based on the first intermediary output signal and the third intermediary output signal.

4. The circuit apparatus of claim 1, wherein, in a third region of the input voltage range between the first region of the input voltage range and the second region of the input voltage range, the first intermediary output signal transitions between substantially following the input signal to being substantially constant.

5. The circuit apparatus of claim 1, wherein, in a third region of the input voltage range between the first region of the input voltage range and the second region of the input voltage range, the second intermediary output signal transition between being substantially constant to substantially following the input signal.

6. The circuit apparatus of claim 1, wherein the NFET circuit of the first stage includes two N-type transistors that are coupled to a first power supply.

7. The circuit apparatus of claim 6, wherein the PFET circuit of the first stage includes two P-type transistors that are coupled to a second power supply.

8. The circuit apparatus of claim 7, wherein the first stage further includes a second NFET circuit coupled in parallel with the NFET circuit, and wherein the second NFET circuit includes two N-type transistors that are coupled to the second power supply.

9. The circuit apparatus of claim 8, wherein the first stage further includes a second PFET circuit coupled in parallel with the PFET circuit, and wherein the second PFET circuit includes two P-type transistors that are coupled to the first power supply.

10. A circuit apparatus, comprising:
a P-type field effect transistor (PFET) circuit of a first stage comprising:
a first PFET including a gate coupled to a first power supply, a drain coupled to an input port, and a source; and
a second PFET including a gate coupled to the input port, a drain coupled to the first power supply, and a source coupled to the source of the first PFET; and
an N-type field effect transistor (NFET) circuit of the first stage comprising:
a first NFET including a gate coupled to a second power supply, a drain coupled to the input port, and a source; and
a second NFET including a gate coupled to the input port, a drain coupled to the second power supply, and a source coupled to the source of the first NFET.

11. The circuit apparatus of claim 10, further comprising a second stage comprising:
a first transistor including a gate coupled to the respective sources of the first PFET and the second PFET, a source coupled to a third power supply, and a drain, and
a second transistor including a gate coupled to the respective sources of the first NFET and the second NFET, a source coupled to ground, and a drain coupled to the drain of the first transistor.

12. The circuit apparatus of claim 11, wherein the first transistor is a first laterally diffused metal oxide semiconductor (LDMOS) transistor and the second transistor is a second LDMOS transistor.

13. The circuit apparatus of claim 11, further comprising a third stage comprising:
a third NFET including a gate connected to the respective drains of the first and second transistors, a drain connected to the second power supply, and a source connected to a resistor; and
a fourth NFET including a gate coupled to the respective sources of the first NFET and the second NFET, a drain connected to the resistor and an output port, and a source coupled to the ground.

14. The circuit apparatus of claim 10, further comprising:
a second NFET circuit of the first stage, including:
a third NFET including a gate coupled to the first power supply, a drain coupled to the input port, and a source; and
a fourth NFET including a gate coupled to the input port, a drain coupled to the first power supply, and a source coupled to the source of the third NFET.

15. The circuit apparatus of claim 14, further comprising:
a second PFET circuit of the first stage, including:
a third PFET including a gate coupled to the second power supply, a drain coupled to the input port, and a source; and
a fourth PFET including a gate coupled to the input port, a drain coupled to the second power supply, and a source coupled to the source of the third PFET.

16. The circuit apparatus of claim 15, further comprising a second stage, including:
a first transistor including a gate coupled to the respective sources of the first PFET and the second PFET, a source coupled to a third power supply, and a drain;
a second transistor including a gate coupled to the respective sources of the first NFET and the second NFET, a source coupled to ground, and a drain coupled to the drain of the first transistor;
a third transistor including a gate coupled to the respective sources of the third PFET and the fourth PFET, a source coupled to the third power supply, and a drain coupled to the respective drains of the first and second transistors; and
a fourth transistor including a gate coupled to the respective sources of the third NFET and the fourth NFET, a source coupled to ground, and a drain coupled to the respective drains of the first and second transistors.

17. The circuit apparatus of claim 16, wherein the first, second, third, and fourth transistors are each a laterally diffused metal oxide semiconductor (LDMOS) transistor.

18. The circuit apparatus of claim 16, further comprising a third stage comprising:
a fifth NFET including a gate connected to the respective drains of the first and second transistors, a drain connected to the second power supply, and a source connected to a resistor; and
a sixth NFET including a gate coupled to the respective sources of the first NFET and the second NFET, a drain connected to the resistor and an output port, and a source coupled to the ground.

19. The circuit apparatus of claim 18, wherein the third stage further comprises:
a seventh NFET including a gate connected to the respective sources of the third NFET and the fourth NFET, a drain connected to the resistor and the output port, and a source coupled to the ground.

20. The circuit apparatus of claim 16, wherein at least one of the first, second, third, and fourth transistors include a triple stack cascade structure.
